(19) United States
(12) Patent Application Publication
(10) Pub. No.: US 2026/0305131 A1
(43) Pub. Date: Oct. 1, 2026

(54) DISPLAY DEVICE AND ELECTRONIC DEVICE INCLUDING THE SAME

(71) Applicant: Samsung Display Co., Ltd., Yongin-si (KR)

(72) Inventors: Yunyoung LEE, Yongin-si (KR); SANGHYO PARK, Yongin-si (KR); IN SOO PARK, Yongin-si (KR)

(21) Appl. No.: 19/552,789

(22) Filed: Feb. 27, 2026

(30) Foreign Application Priority Data
Mar. 31, 2025 (KR) 10-2025-0041385
Aug. 7, 2025 (KR) 10-2025-0108862

(51) Int. Cl. H10K 59/80; G06F 1/16; H10K 102/00

(52) U.S. Cl. CPC H10K 59/8722; G06F 1/1641; G06F 1/1656; G06F 1/1681; H10K 2102/311; H10K 2102/351

(57) ABSTRACT

A display device includes: a display panel having a first non-folding area, a second non-folding area, and a folding area between the first non-folding area and the second non-folding area; a glass substrate over the display panel; and an adhesive member between the display panel and the glass substrate. The adhesive member has a stress relaxation (SR) in a range of 70% to 85%, and the stress relaxation (SR) of the adhesive member is given by the following equation:

$$SR = [ 1 - ( {X}_{2} / {X}_{1} ) ] \times 100 \%$$

In which X₁ is a first shear stress measured immediately after application of 25% shear strain at a temperature of 25° C., and X₂ is a second shear stress measured 1 hour after the application of 25% shear strain at a temperature of 25° C.

### CROSS-REFERENCE TO RELATED APPLICATIONS

The present application claims priority to and the benefit of Korean Patent Application No. 10-2025-0041385, filed on Mar. 31, 2025 in the Korean Intellectual Property Office and Korean Patent Application No. 10-2025-0108862, filed on Aug. 7, 2025, in the Korean Intellectual Property Office, the entire disclosure of each of which is incorporated herein by reference.

### BACKGROUND

### 1. Field

Aspects of embodiments of the present disclosure relate to a display device and an electronic device including the same.

### 2. Description of the Related Art

A display device includes a display area that is activated in response to an electrical signal. The display device may sense an input applied from the outside through the display area while displaying various images to provide information to a user. With the development of display devices having various shapes, display areas having various shapes are being implemented.

### SUMMARY

Embodiments of the present disclosure provide a foldable display device having improved folding characteristics and durability.

Embodiments of the present disclosure provide an electronic device including the display device.

According to an embodiment, a display device includes a display panel having a first non-folding area, a second non-folding area, and a folding area between the first non-folding area and the second non-folding area, a glass substrate over the display panel, and an adhesive member between the display panel and the glass substrate, in which the adhesive member has a stress relaxation (SR) in a range of 70% to 85%, and the stress relaxation (SR) of the adhesive member is given by Equation 1:

$$SR = [ 1 - ( {X}_{2} / {X}_{1} ) ] \times 100 \%$$

In which, X₁ is a first shear stress measured immediately after application of 25% shear strain at a temperature of 25° C., and X₂ is a second shear stress measured 1 hour after the application of 25% shear strain at a temperature of 25° C.

The folding area may extend in a first direction, and the first non-folding area and the second non-folding area may be spaced apart from each other in a second direction crossing the first direction.

The adhesive member may include a pressure sensitive adhesive.

The adhesive member may have a creep strain in a range of 100% to 150% at a temperature of 25° C.

The adhesive member may be directly on the display panel.

The adhesive member may have a thickness in a range of 30 μm to 150 μm.

The display device may further include a protective member over the glass substrate and an upper adhesive member between the protective member and the glass substrate. The upper adhesive member may have a stress relaxation in a range of 70% to 85%, and the stress relaxation of the upper adhesive member may be given by Equation 1.

The display device may further include a panel protection layer under the display panel and a first lower adhesive member between the display panel and the panel protection layer. The first lower adhesive member may have a stress relaxation in a range of 70% to 85%, and the stress relaxation of the first lower adhesive member may be given by Equation 1.

The display device may further include a support plate under the panel protection layer and a second lower adhesive member between the panel protection layer and the support plate. The second lower adhesive member may have a stress relaxation in a range of 70% to 85%, and the stress relaxation of the second lower adhesive member may be given by Equation 1.

According to an embodiment, an electronic device includes a display device, a hinge assembly coupled to the display device and that is configured to convert the display device between an unfolded state and a folded state, and a housing coupled to the display device and the hinge assembly. The display device includes a display panel, a glass substrate over the display panel, and an adhesive member between the display panel and the glass substrate. The adhesive member has a stress relaxation (SR) in a range of 70% to 85%, and the stress relaxation (SR) of the adhesive member is given by Equation 1.

The display device may further include a protective member on the glass substrate, and the protective member may be attached to the housing.

The display panel may have a first non-folding area, a second non-folding area, and a folding area between the first non-folding area and the second non-folding area.

The hinge assembly may include a center frame corresponding to the folding area, a first frame that corresponds to the first non-folding area and that is hinged to the center frame through a first shaft located inside the center frame, and a second frame that corresponds to the first non-folding area and that is hinged to the center frame through a second shaft, with the second shaft being located inside the center frame and farther away from the display device than the first shaft is. The display device may be coupled to the second frame.

The hinge assembly may cause a slip between the protective member, the glass substrate, the adhesive member, and the display panel in the folded state.

The adhesive member may slip more than the glass substrate with respect to the protective member, and the display panel may slip more than the adhesive member with respect to the protective member.

The adhesive member in the unfolded state may be at least partially stretched in a direction toward the housing when compared to the adhesive member in the folded state.

### BRIEF DESCRIPTION OF THE DRAWINGS

The above and other aspects and features of the present disclosure will become apparent by describing, in detail, embodiments thereof with reference to the accompanying drawings, in which:

FIG. 1 is a block diagram describing an electronic device according to an embodiment of the present disclosure.

FIG. 2 includes schematic views of electronic devices according to embodiments of the present disclosure.

FIGS. 3A and 3B are perspective views of an electronic device according to an embodiment of the present disclosure.

FIG. 4A is an exploded perspective view of an electronic device according to an embodiment of the present disclosure.

FIG. 4B is a plan view of a display panel according to an embodiment of the present disclosure.

FIG. 4C is a cross-sectional view of the display panel shown in FIG. 4B according to an embodiment of the present disclosure.

FIGS. 5A and 5B are cross-sectional views of a display device according to an embodiment of the present disclosure.

FIG. 6A is a side view illustrating an unfolded state of the electronic device according to an embodiment of the present disclosure.

FIG. 6B is a side view illustrating a folded state of the electronic device according to an embodiment of the present disclosure.

FIGS. 7A and 7B are cross-sectional views illustrating some components of an electronic device according to an embodiment of the present disclosure.

FIG. 7C is an enlarged cross-sectional view illustrating some components of the electronic device according to an embodiment of the present disclosure.

FIGS. 8A and 8B are graphs illustrating calculation of a crease reduction rate of an electronic device according to an embodiment of the present disclosure.

FIGS. 9A and 9B are graphs illustrating calculation of a crease reduction rate of an electronic device according to a comparative example.

### DETAILED DESCRIPTION

In this specification, when a component (or an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components may be exaggerated for effective description. As used herein, the term “and/or” includes all of one or more combinations defined by related components.

Terms such as first, second, and the like may be used to describe various components, but the components should not be limited by the terms. The terms may be used only for distinguishing one component, part, area, layer, or portion from other components, parts, areas, layers, or portions. For example, without departing the scope and scope of the present disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms, such as “comprise”, “include”, and “have”, when used herein, specify the presence of stated features, numbers, steps, operations, components, parts, or combinations thereof but do not preclude the presence or addition of one or more other features, numbers, steps, operations, components, parts, or combinations thereof.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art and are not to be interpreted as having ideal or excessively formal meanings unless clearly defined as having such in the present application.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described with reference to the accompanying drawings.

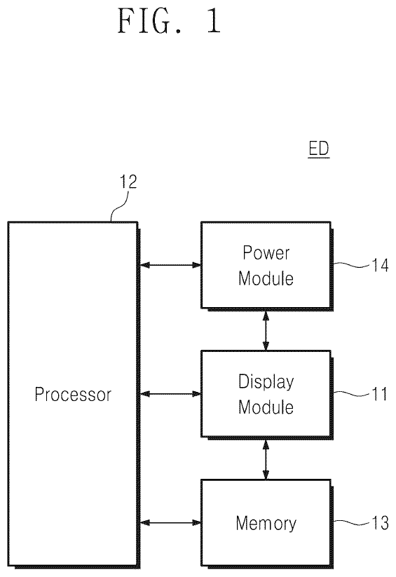

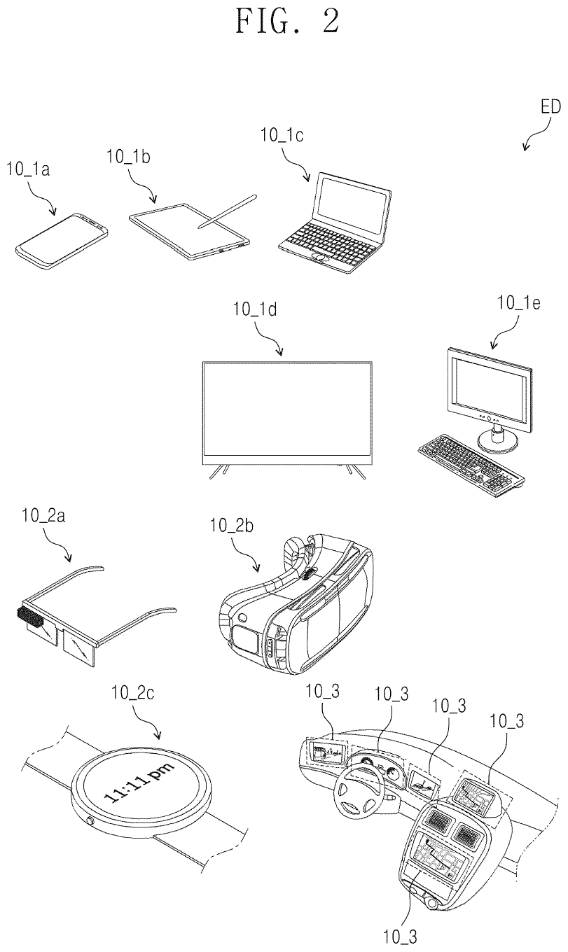

FIG. 1 is a block diagram describing an electronic device ED according to an embodiment of the present disclosure. FIG. 2 includes schematic views of electronic devices ED according to embodiments of the present disclosure.

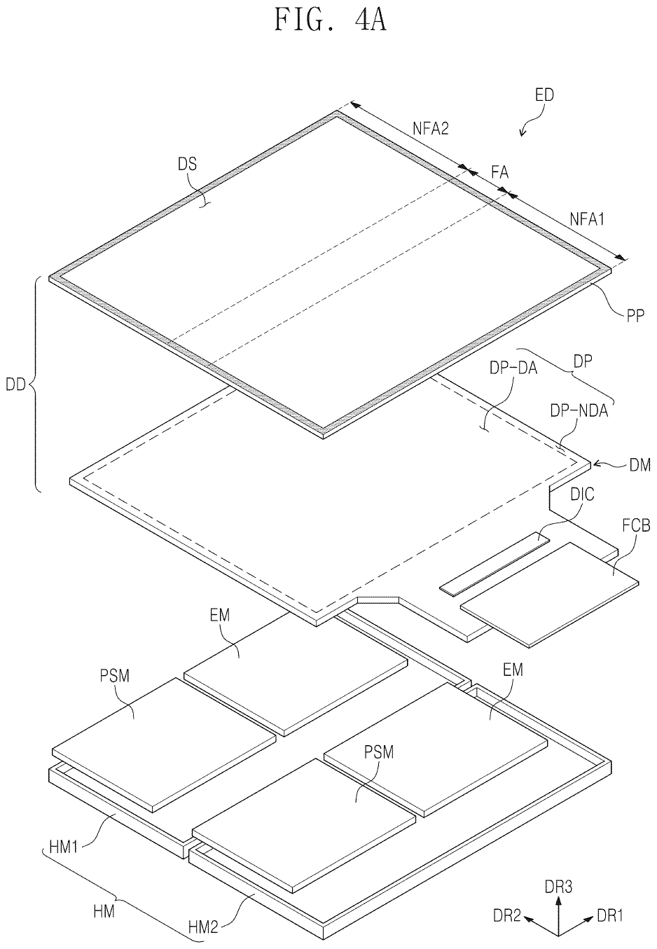

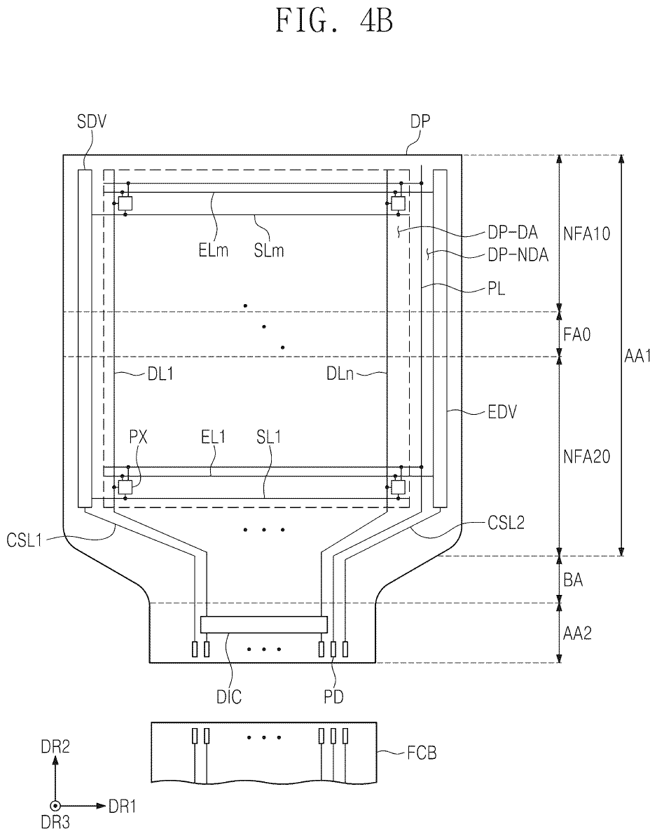

Referring to FIG. 1, the electronic device ED, according to an embodiment, may include a display device 11, a processor 12, a memory 13, and a power module 14. In this specification, the display device 11 may be described as or referred to as a display device DD (see, e.g., FIG. 4A).

The processor 12 may include at least one of a central processing unit (CPU), an application processor (AP), a graphic processing unit (GPU), a communication processor (CP), an image signal processor (ISP), and a controller.

Data information required for operation of the processor 12 or the display device 11 may be stored in the memory 13. When the processor 12 executes an application stored in the memory 13, an image data signal and/or an input control signal may be transferred to the display device 11, and the display device 11 may process the provided signal and may output image information through a display screen.

The power module 14 may include a power supply module, such as a power adapter or a battery device, and a power conversion module that converts power supplied by the power supply module and generates power required for operation of the electronic device ED.

The processor 12, the power module 14, and the memory 13 described above may be included in the display device 11 or may be separate modules distinguished from the display device 11. Within the housing that forms the exterior of the electronic device ED, the processor 12, the power module 14, and the memory 13 may be located in a form distinguished from the display device 11.

Referring to FIG. 2, the electronic devices ED according to embodiments of the present disclosure may include not only typical information-providing electronic devices, such as a smart phone 10_1a, a tablet PC 10_1b, a laptop computer 10_1c, a TV 10_1d, and a desk monitor 10_1e, but also wearable electronic devices, such as smart glasses 10_2a, a head mounted display device 10_2b, and a smart watch 10_2c, and vehicle electronic devices 10_3, such as center information displays (CIDs) located on an instrument panel, a center fascia, and a dashboard of a vehicle and a room mirror display.

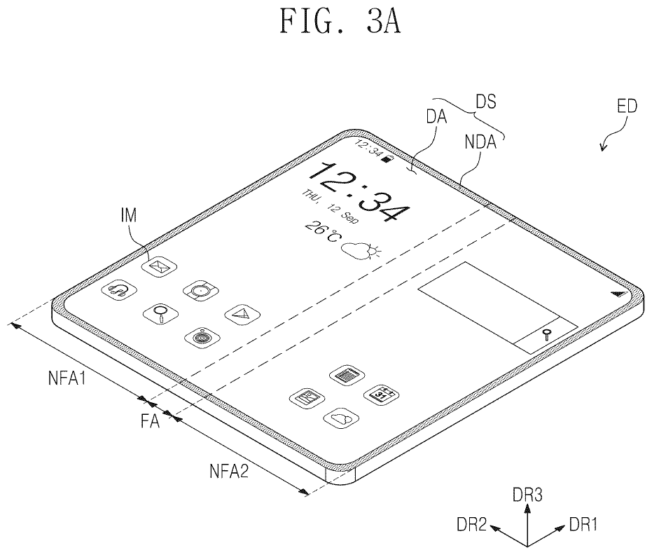

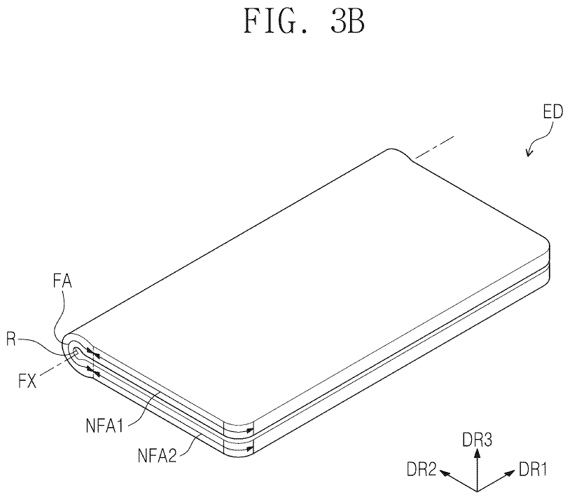

FIGS. 3A and 3B are perspective views of the electronic device ED according to an embodiment of the present disclosure. FIG. 3A and FIG. 3B illustrate an electronic device for displaying images, which may be the smart phone 10_1a, the tablet PC 10_1b, the laptop computer 10_1c, the TV 10_1d, and the desk monitor 10_1e illustrated in FIG. 2, as an example, and may be applied to various electronic devices without being limited to the illustrated form.

Referring to FIG. 3A, the electronic device ED according to an embodiment of the present disclosure may have short sides extending in a first direction DR1 and long sides extending in a second direction DR2 crossing the first direction DR1. The electronic device ED may have a rounded quadrangular shape in which the corners have a round shape. The electronic device ED may be a flexible display device.

Hereinafter, a direction substantially perpendicular to a plane defined by the first direction DR1 and the second direction DR2 is defined as a third direction DR3. The expression “when viewed from above the plane” used herein may mean that it is viewed in the third direction DR3. The term “overlap” used herein may be defined as portions of components that overlap each other when viewed from above the plane.

The electronic device ED may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The first non-folding area NFA1, the folding area FA, and the second non-folding area NFA2 may be arranged in the first direction DR1.

Although one folding area FA and two non-folding areas NFA1 and NFA2 are illustrated as an example, the number of folding areas FA and the number of non-folding areas NFA1 and NFA2 are not limited thereto. For example, the electronic device ED may include more than two non-folding areas and a plurality of folding areas disposed between the non-folding areas.

The upper surface of the electronic device ED may be defined as a display surface DS, and the display surface DS may have a plane defined by the first direction DR1 and the second direction DR2. Images IM generated by the electronic device ED may be provided to a user through the display surface DS.

The display surface DS may include a display area DA and a non-display area NDA around (e.g., extending around or surrounding a periphery of) the display area DA. The display area DA may display an image, and the non-display area NDA may not display an image (e.g., an image may be displayed at the display area DA while no image is displayed at the non-display area NDA). The non-display area NDA may surround a periphery of the display area DA and may define the border of the electronic device ED that is printed in a certain color.

Referring to FIG. 3B, the electronic device ED may be a foldable electronic device ED. For example, the folding area FA may be bent about a folding axis FX parallel to the first direction DR1 so that the electronic device ED may be folded. The folding axis FX may be defined as a long axis parallel to the long sides of the electronic device ED. However, without being limited thereto, the folding axis FX may be defined as a short axis parallel to the short sides of the electronic device ED, and the electronic device ED may be folded about the folding axis parallel to the short sides of the electronic device ED.

When the electronic device ED is folded, the first non-folding area NFA1 and the second non-folding area NFA2 may face each other, and the electronic device ED may be folded in an in-folding manner such that the display surface DS is not exposed to the outside. However, embodiments of the present disclosure are not limited thereto. For example, the electronic device ED may be folded about the folding axis FX in an out-folding manner such that the display surface DS is exposed to the outside in a folded state.

The distance between the first non-folding area NFA1 and the second non-folding area NFA2 may be smaller than the diameter of the circle defined by the radius of curvature R of the folding area FA. In such an embodiment, the folding area FA may be folded in a dumbbell shape, and the first non-folding area NFA1 and the second non-folding area NFA2 may become closer to each other (e.g., may become closer to each other away from the folding area FA).

FIG. 4A is an exploded perspective view of the electronic device ED according to an embodiment of the present disclosure. FIG. 4B is a plan view of a display panel according to an embodiment of the present disclosure. FIG. 4C is a cross-sectional view of the display panel according to an embodiment of the present disclosure. In more detail, FIG. 4C is a cross-sectional view of the display panel corresponding to one pixel as illustrated in FIG. 4B.

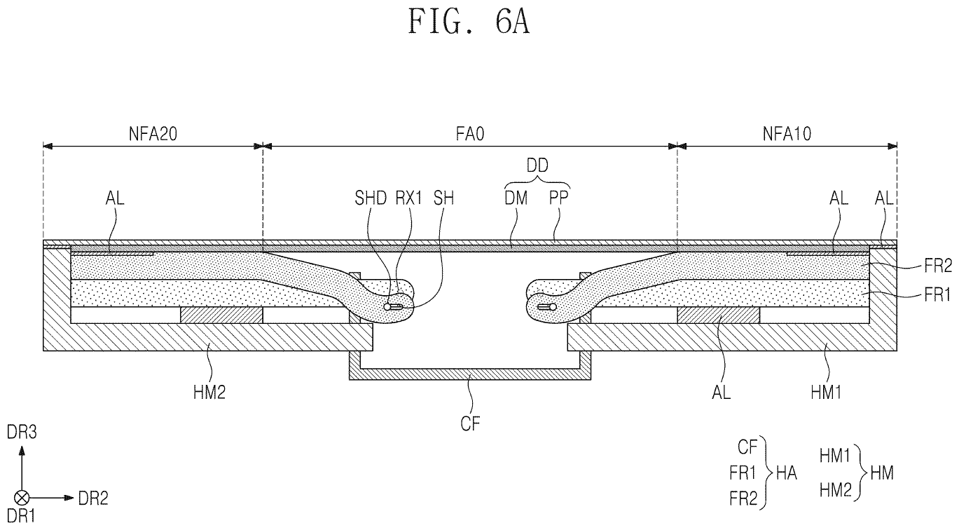

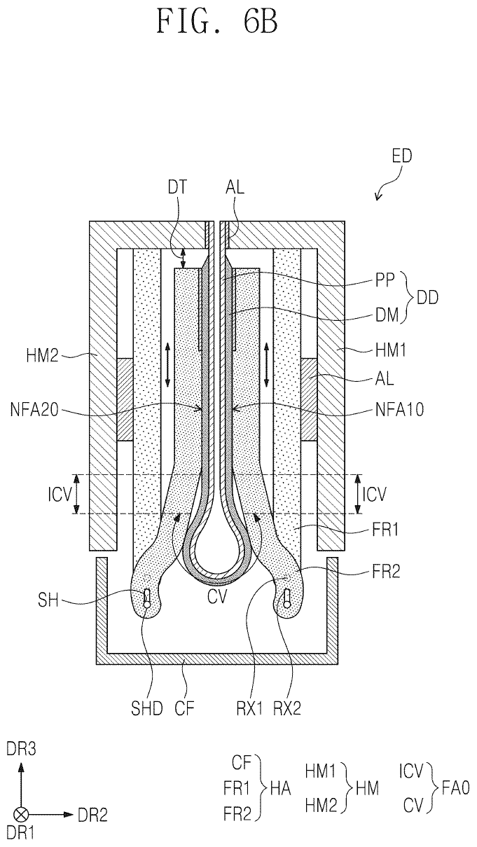

Referring to FIG. 4A, the electronic device ED may include the display device DD, electronic modules EM, power supply modules PSM, and a housing HM. The electronic device ED may further include a hinge assembly HA (see, e.g., FIGS. 6A and 6B) for controlling a folding operation of the electronic device ED.

The display device DD may generate an image and may sense an external input. The display device DD may include a protective member PP (e.g., a protective plate or a protective film) and a display module DM. The protective member PP provides the front surface of the display device DD and the electronic device ED. The electronic device ED may include the display surface DS provided through the protective member PP.

The display module DM may include at least the display panel DP. The display panel DP is not particularly limited and may include, for example, an emissive display panel, such as an organic light emitting display panel or an inorganic light emitting display panel.

The display panel DP has a display area DP-DA and a non-display area DP-NDA. The display area DP-DA and the non-display area DP-NDA may correspond to the display area DA (see, e.g., FIG. 3A) and the non-display area NDA (see, e.g., FIG. 3A) of the display surface DS described above.

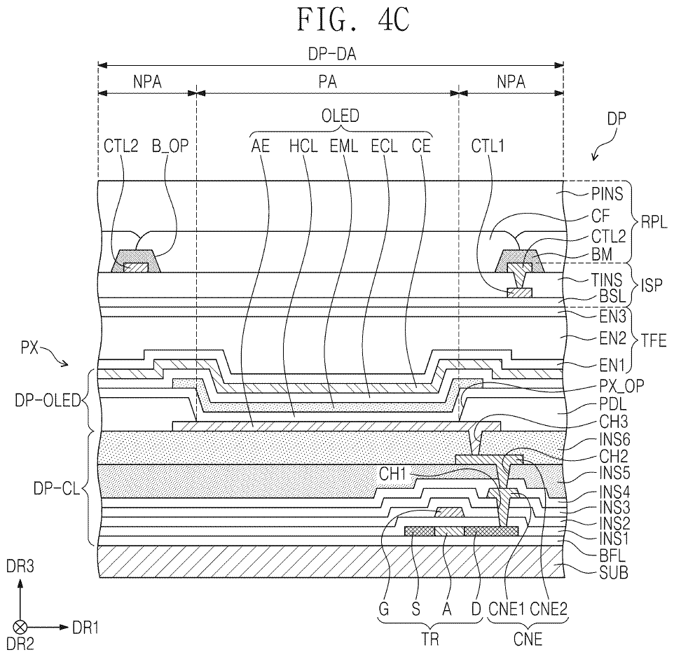

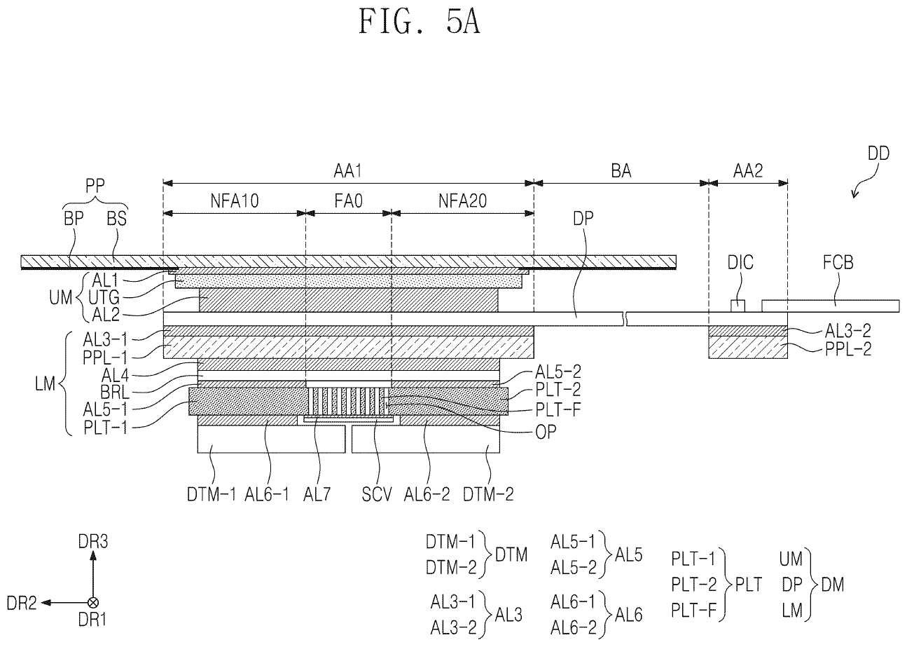

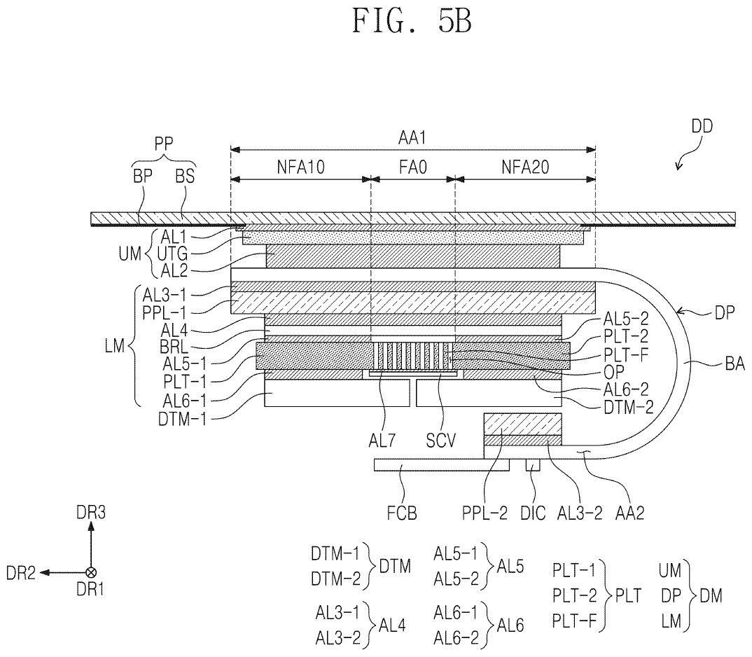

FIG. 4A primarily illustrates the display panel DP from among stacked structures of the display module DM, and the display module DM may further include an upper member UM (see, e.g., FIG. 5A) disposed over the display panel DP and located under the protective member PP and a lower member LM (see, e.g., FIG. 5A) located under the display panel DP. The stacked structures of the display module DM will be described below in more detail.

The display module DM may further include a driver chip DIC and a flexible circuit board FCB. The driver chip DIC may be disposed on the non-display area DP-NDA of the display panel DP. The flexible circuit board FCB may be coupled to the non-display area DP-NDA of the display panel DP. The flexible circuit board FCB may be connected to a main circuit board.

The driver chip DIC may include driving elements for driving pixels of the display panel DP, for example, a data driver circuit. FIG. 4 illustrates an embodiment in which the driver chip DIC is mounted on the display panel DP, but the present disclosure is not limited thereto. For example, in another embodiment, the driver chip DIC may be mounted on the flexible circuit board FCB.

The electronic modules EM may include the processor 12 and the memory 13 as shown in, for example, FIG. 1. The electronic modules EM may include the main circuit board, and the processor 12 and the memory 13 may be mounted on the main circuit board or may be electrically connected to the main circuit board through a flexible circuit board. The electronic modules EM are electrically connected to the power supply modules PSM.

The housing HM is coupled with the display device DD, in particular, with the protective member PP and protects other modules. FIG. 4A illustrates an embodiment in which that the housing HM includes a first housing HM1 and a second housing HM2 that correspond to the first non-folding area NFA1 and the second non-folding area NFA2, respectively.

The electronic modules EM may be disposed in the first housing HM1 and the second housing HM2, respectively, and the power supply modules PSM may be disposed in the first housing HM1 and the second housing HM2, respectively. The electronic module EM located in the first housing HM1 and the electronic module EM located in the second housing HM2 may be electrically connected through a flexible circuit board, and the two electronic modules EM may include different components.

The electronic device ED may further include an electro-optical module. The electro-optical module may be an electronic component that outputs or receives an optical signal. The electro-optical module may include a camera module and/or a proximity sensor. The camera module may take an external image through a partial area of the display panel DP.

The display panel DP will be described in more detail with reference to FIG. 4B. Pixels PX may be located in the display area DP-DA. A scan driver circuit SDV, the data driver circuit, and an emission driver circuit EDV may be located in the non-display area DP-NDA. The data driver circuit may be included in the driver chip DIC.

The display panel DP may have a first portion AA1, a second portion AA2, and a third portion BA distinguished from one another in (e.g., adjacent to each other in) the second direction DR2. The second portion AA2 and the third portion BA may be partial areas of the non-display area DP-NDA. The third portion BA may be defined between the first portion AA1 and the second portion AA2.

The first portion AA1 may face the protective member PP shown in FIG. 4A. The first portion AA1 may include a first non-folding area NFA10, a second non-folding area NFA20, and a folding area FAO that correspond to the first non-folding area NFA1, the second non-folding area NFA2, and the folding area FA of the electronic device ED. The first non-folding area NFA10, the second non-folding area NFA20, and the folding area FAO of the first portion AA1 may be identically applied (or present in) not only to the display panel DP but also to (or in) the display device DD itself shown in FIG. 4A and other components of the display module DM.

The third portion BA may have a shorter length in the first direction DR1 than that of the first portion AA1. The third portion BA may have a gradually decreasing length in the first direction DR1 toward the second portion AA2 in the second direction DR2 (e.g., the third portion BA may be tapered toward the second portion AA2). Accordingly, the third portion BA may be more easily bent.

The display panel DP may include a plurality of pixels PX, a plurality of scan lines SL1 to SLm, a plurality of data lines DL1 to DLn, a plurality of emission lines EL1 to ELm, a first control line CSL1, a second control line CSL2, a power line PL (e.g., a power voltage line), and a plurality of pads PD. Here, “m” and “n” are natural numbers. The pixels PX may be connected to the scan lines SL1 to SLm, the data lines DL1 to DLn, and the emission lines EL1 to ELm.

The scan lines SL1 to SLm may extend in the first direction DR1 and may be connected to the scan driver circuit SDV. The data lines DL1 to DLn may extend in the second direction DR2 and may be connected to the driver chip DIC via the third portion BA. The emission lines EL1 to ELm may extend in the first direction DR1 and may be connected to the emission driver circuit EDV.

The power line PL may include a portion extending in the second direction DR2 and a portion extending in the first direction DR1. The portion extending in the first direction DR1 and the portion extending in the second direction DR2 may be disposed on different layers. The portion of the power line PL that extends in the second direction DR2 may extend to the second portion AA2 via the third portion BA. The power line PL may provide a first voltage to the pixels PX.

The first control line CSL1 may be connected to the scan driver circuit SDV and may extend toward the lower end of the second portion AA2 via the third portion BA. The second control line CSL2 may be connected to the emission driver circuit EDV and may extend toward the lower end of the second portion AA2 via the third portion BA.

The pads PD may be disposed adjacent to the lower end of the second portion AA2 when viewed from above the plane. The driver chip DIC, the power line PL, the first control line CSL1, and the second control line CSL2 may be connected to the pads PD. The flexible circuit board FCB may be electrically connected to the pads PD through an anisotropic conductive adhesive layer.

Referring to FIG. 4C, the display panel DP may include a pixel PX, and the pixel PX may include a transistor TR and a light emitting element OLED. The light emitting element OLED may include a first electrode AE (e.g., an anode), a second electrode CE (e.g., a cathode), a hole control layer HCL, an electron control layer ECL, and a light emitting layer EML.

The transistor TR and the light emitting element OLED may be disposed on a substrate SUB. Although one transistor TR is illustrated as an example, the pixel PX may include a plurality of transistors and at least one capacitor for driving the light emitting element OLED.

The display area DP-DA may have a light emitting area PA corresponding to each of the pixels PX and a non-light emitting area NPA around (e.g., extending around a periphery of) the light emitting area PA. The light emitting element OLED may be disposed in the light emitting area PA.

The display panel DP may include the substrate SUB, a circuit element layer DP-CL disposed on the substrate SUB, a display element layer DP-OLED disposed on the circuit element layer DP-CL, a thin film encapsulation layer TFE disposed on the display element layer DP-OLED, an input sensing part ISP disposed on the thin film encapsulation layer TFE, and an anti-reflective layer RPL disposed on the input sensing part ISP.

A buffer layer BFL may be disposed on the substrate SUB. The buffer layer BFL may be an inorganic layer. A semiconductor pattern may be disposed on the buffer layer BFL. The semiconductor pattern may include poly silicon, amorphous silicon, or metal oxide.

The semiconductor pattern may be doped with an N-type dopant or a P-type dopant. The semiconductor pattern may include highly doped areas and a lightly doped area. The highly doped areas may have a higher conductivity than the lightly doped area and may respectively act as a source electrode and a drain electrode of the transistor TR. The lightly doped area may correspond to an active area (e.g., a channel) of the transistor TR.

The source S, the active area A, and the drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connecting electrode CNE may include a first connecting electrode CNE1 and a second connecting electrode CNE2 to connect the transistor TR and the light emitting element OLED. The first connecting electrode CNE1 may be disposed on the third insulating layer INS3 and may be connected to the drain D through a first contact hole CH1 defined in the first to third insulating layers INS1 to INS3.

A fourth insulating layer INS4 may be disposed on the first connecting electrode CNE1. A fifth insulating layer INS5 may be disposed on the fourth insulating layer INS4. The second connecting electrode CNE2 may be disposed on the fifth insulating layer INS5. The second connecting electrode CNE2 may be connected to the first connecting electrode CNE1 through a second contact hole (or opening) CH2 defined in the fourth insulating layer INS4 and the fifth insulating layer INS5.

A sixth insulating layer INS6 may be disposed on the second connecting electrode CNE2. The layers from the buffer layer BFL to the sixth insulating layer INS6 may be defined as the circuit element layer DP-CL. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole (or opening) CH3 defined in the sixth insulating layer INS6. A pixel defining layer PDL having an opening PX_OP defined therein to expose a certain portion of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The light emitting layer EML may be disposed on the hole control layer HCL. The light emitting layer EML may be disposed in the area corresponding to the opening PX_OP. The light emitting layer EML may include an organic material and/or an inorganic material. The light emitting layer EML may generate one of red light, green light, and blue light.

The electron control layer ECL may be disposed on the light emitting layer EML and the hole control layer HCL. The electron control layer ECL may include an electron transport layer and an electron injection layer. The hole control layer HCL and the electron control layer ECL may be commonly disposed in the light emitting area PA and the non-light emitting area NPA.

The second electrode CE may be disposed on the electron control layer ECL. The second electrode CE may be commonly disposed in the pixels PX. The layer in which the light emitting element OLED is disposed may be defined as the display element layer DP-OLED.

The thin film encapsulation layer TFE may be disposed on the second electrode CE and may cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first encapsulation layer EN1 and the third encapsulation layer EN3 may include an inorganic insulating layer and may protect the pixel PX from moisture/oxygen. The second encapsulation layer EN2 may include an organic insulating layer and may protect the pixel PX from foreign matter, such as dust particles.

The first voltage may be applied to the first electrode AE through the transistor TR, and the second voltage having a lower level than the first voltage may be applied to the second electrode CE. Holes and electrons injected into the light emitting layer EML may be combined to form excitons, and as the excitons transition to a ground state, the light emitting element OLED may emit light.

The input sensing part ISP may be disposed on the thin film encapsulation layer TFE. The input sensing part ISP may be directly manufactured on the upper surface of the thin film encapsulation layer TFE.

A sensor base layer BSL may be disposed on the thin film encapsulation layer TFE. The sensor base layer BSL may include an inorganic insulating layer. At least one inorganic insulating layer may be provided as the sensor base layer BSL on the thin film encapsulation layer TFE.

The input sensing part ISP may include a first conductive pattern CTL1 and a second conductive pattern CTL2 disposed on the first conductive pattern CTL1. The first conductive pattern CTL1 may be disposed on the sensor base layer BSL. An insulating layer TINS may be disposed on the sensor base layer BSL to cover the first conductive pattern CTL1. The insulating layer TINS may include an inorganic insulating layer or an organic insulating layer. The second conductive pattern CTL2 may be disposed on the insulating layer TINS.

The first conductive pattern CTL1 and the second conductive pattern CTL2 may overlap the non-light emitting area NPA. The first conductive pattern CTL1 and the second conductive pattern CTL2 may be disposed on the non-light emitting area NPA between the light emitting areas PA and may have a mesh shape.

The first conductive pattern CTL1 and the second conductive pattern CTL2 may form sensors of the input sensing part ISP described above. For example, the first conductive pattern CTL1 and the second conductive pattern CTL2 having a mesh shape may be separated from each other at a certain areas to form sensors. A portion of the second conductive pattern CTL2 may be connected to the first conductive pattern CTL1.

The anti-reflective layer RPL may be disposed on the second conductive pattern CTL2. The anti-reflective layer RPL may include a black matrix BM and a plurality of color filters CF. The black matrix BM may overlap the non-light emitting area NPA, and the color filters CF may overlap the light emitting areas PA, respectively.

The black matrix BM may be disposed on the insulating layer TINS to cover the second conductive pattern CTL2. An opening B_OP that overlaps the light emitting area PA and the opening PX_OP may be defined in the black matrix BM. The black matrix BM may absorb and block light. The opening B_OP may have a greater width than the corresponding opening PX_OP.

The color filters CF may be disposed on the insulating layer TINS and the black matrix BM. The color filters CF may be disposed in the openings B_OP, respectively. A planarization insulating layer PINS may be disposed on the color filters CF. The planarization insulating layer PINS may provide a flat upper surface.

When external light traveling toward the display panel DP is reflected by the display panel DP and then provided back to the user, the user may visually recognize the external light, similar to a mirror. To prevent such a phenomenon, for example, the anti-reflective layer RPL may include the color filters CF that display the same colors as the pixels PX of the display panel DP. The color filters CF may filter the external light in the same colors as the pixels. In such an embodiment, the external light may not be visible to the user.

However, embodiments of the present disclosure are not limited thereto, and the anti-reflective layer RPL may include a polarizer film to decrease the reflectance of the external light. The polarizer film may be separately manufactured and may be attached to the input sensing part ISP by an adhesive layer. The polarizer film may include a phase retarder and/or a polarizer.

FIGS. 5A and 5B are cross-sectional views of the display device DD according to an embodiment of the present disclosure. When compared to FIG. 4A, FIGS. 5A and 5B additionally illustrate the upper member UM and the lower member LM as components of the display module DM. The upper member UM and the lower member LM, to be described below, are merely examples, and the configurations of the upper member UM and the lower member LM are not limited.

In FIGS. 5A and 5B, the display device DD is illustrated in an unfolded state as an example. FIG. 5A illustrates a state before the third portion BA of the display panel DP is bent, and FIG. 5B illustrates a state after the third portion BA of the display panel DP is bent. As illustrated in FIG. 5B, the second portion AA2 is located under the lower member LM when the first portion AA1 faces the protective member PP in a state in which the third portion BA is bent to have a curvature.

Referring to FIGS. 5A and 5B, the protective member PP may be defined as a structure attached to a housing (see, e.g., FIGS. 6A and 6B) to be described below. The protective member PP may include at least one base layer BS and may have a single-layer structure or a multi-layer structure. The base layer BS may include a plastic film or a glass substrate. The base layer BS may have a thickness of about 100 μm or less, for example, a thickness of about 50 μm to about 80 μm.

The base layer BS may include polyimide, polycarbonate, polyamide, triacetyl cellulose, polymethylmethacrylate, or polyethylene terephthalate.

The protective member PP may further include a functional coating layer disposed on the upper surface of the base layer BS. The functional coating layer may include at least one of a hard coating layer, an anti-fingerprint layer, and an anti-reflective layer.

The protective member PP may further include a bezel pattern BP located on the lower surface of the base layer BS. The bezel pattern BP may be a colored light-blocking film and may be formed, for example, by a coating method. The bezel pattern BP may be a black light-blocking film. The bezel pattern BP may include a base material and a dye or pigment mixed in the base material.

The bezel pattern BP defines a bezel area of the electronic device ED (see, e.g., FIG. 4A). The bezel pattern BP overlaps the non-display area DP-NDA (see, e.g., FIG. 4A) of the display device DD when viewed from above the plane. In an embodiment, the bezel pattern BP may be omitted or may be located on another layer of the upper member UM.

The upper member UM may include a glass substrate UTG and adhesive layers AL1 and AL2. In this embodiment, the upper member UM may include the first adhesive layer AL1 that attaches the protective member PP and the glass substrate UTG to each other and the second adhesive layer AL2 that attaches the glass substrate UTG and the display panel DP to each other. The second adhesive layer AL2 may be directly disposed on the display panel DP. Hereinafter, the second adhesive layer AL2 may be referred to as an adhesive member AL2.

The glass substrate UTG may have a thickness of about 15 μm to about 45 μm. The glass substrate UTG may be chemically strengthened glass. The glass substrate UTG may reduce or minimize a crease even after being repeatedly folded and unfolded.

The adhesive layers AL1 and AL2 may be pressure sensitive adhesive (PSA) films. In another embodiment, the adhesive layers AL1 and AL2 may be optically clear adhesive (OCA) members, and adhesive layers, to be described below, may include the same adhesive.

The upper member UM may further include an upper film between the glass substrate UTG and the display panel DP. The upper film may absorb external impact applied to the front surface of the display device DD. The display panel DP may include the color filters CF (see, e.g., FIG. 4C) that replace a polarizer film, and due to the omission of the polarizer film, the front impact strength of the display device DD may be decreased. The upper film may compensate for the impact strength. The upper film may include a plastic film. The upper film may include polyimide, polycarbonate, polyamide, triacetyl cellulose, polymethylmethacrylate, or polyethylene terephthalate.

The lower member LM may include a panel protection layer PPL, a barrier layer BRL, a support plate PLT, a cover layer SCV, a digitizer DTM, and one or more adhesive layers AL3 to AL7. The lower member LM may include the third to seventh adhesive layers AL3 to AL7. In an embodiment of the present disclosure, some of the components described above may be omitted. For example, the barrier layer BRL, the cover layer SCV, or the digitizer DTM and the adhesive layers relevant thereto may be omitted.

The panel protection layer PPL may be disposed under the display panel DP. The panel protection layer PPL may protect the bottom of the display panel DP. The panel protection layer PPL may include a flexible synthetic resin film. For example, the panel protection layer PPL may include polyethylene terephthalate.

In an embodiment of the present disclosure, the panel protection layer PPL may not be disposed under the third portion BA (see, e.g., FIG. 4B) of the display panel DP. The panel protection layer PPL may include a first panel protection layer PPL-1 that protects the first portion AA1 (see, e.g., FIG. 4B) of the display panel DP and a second panel protection layer PPL-2 that protects the second portion AA2 (see, e.g., FIG. 4B) of the display panel DP.

The third adhesive layer AL3 couples the panel protection layer PPL and the display panel DP to each other. The third adhesive layer AL3 may include a first portion AL3-1 corresponding to the first panel protection layer PPL-1 and a second portion AL3-2 corresponding to the second panel protection layer PPL-2.

The second panel protection layer PPL-2, together with the second portion AA2, may be disposed under the digitizer DTM when the third portion BA is bent. The third portion BA may be more easily bent because the panel protection layer PPL is not disposed under the third portion BA.

The fourth adhesive layer AL4 couples the panel protection layer PPL and the barrier layer BRL to each other. The barrier layer BRL may be disposed under the first panel protection layer PPL-1. The barrier layer BRL may increase resistance to a compressive force caused by external pressing. Accordingly, the barrier layer BRL may suppress deformation of the display panel DP. The barrier layer BRL may include a flexible plastic material, such as polyimide or polyethylene terephthalate. In addition, the barrier layer BRL may be a colored film having low light transmittance. The barrier layer BRL may absorb light incident from the outside. For example, the barrier layer BRL may be a black synthetic resin film. When the display device DD is viewed from above a protective-member protection layer PF, components located under the barrier layer BRL may not be visible to the user.

The fifth adhesive layer AL5 couples the barrier layer BRL and the support plate PLT to each other. The fifth adhesive layer AL5 may have a first portion AL5-1 and a second portion AL5-2 spaced apart from each other. The separation distance between the first portion AL5-1 and the second portion AL5-2 corresponds to the width of the folding area FAO and is greater than the gap by which digitizers, to be described below, are spaced apart from each other.

The support plate PLT is located under the barrier layer BRL. The support plate PLT supports components located thereon and maintains an unfolded state and a folded state of the display device DD. The support plate PLT has a higher strength than the barrier layer BRL.

The support plate PLT may include a high-strength metallic material. The support plate PLT may include a material having an elastic modulus of about 60 GPa or more. The support plate PLT may include a metallic material, such as stainless steel.

The support plate PLT may include a fiber reinforced composite. The support plate PLT may include reinforced fibers located inside a matrix. The reinforced fibers may be carbon fibers or glass fibers. The matrix may include a polymer resin. The matrix may include a thermoplastic resin. For example, the matrix may include a polyamide resin or a polypropylene resin. For example, the reinforced fiber composite may be carbon fiber reinforced plastic (CFRP) or glass fiber reinforced plastic (GFRP).

The support plate PLT includes at least a first support portion PLT-1 corresponding to the first non-folding area NFA10 and a second support portion PLT-2 corresponding to the second non-folding area NFA20. The support plate PLT may include a folding portion PLT-F that corresponds to the folding area FAO and has a plurality of openings OP defined therein and that is disposed between the first support portion PLT-1 and the second support portion PLT-2. The folding portion PLT-F may be more easily deformed when the display device DD is changed from an unfolded state to a folded state.

The plurality of openings OP may form a grid pattern in the folding portion PLT-F. Accordingly, the first support portion PLT-1, the second support portion PLT-2, and the folding portion PLT-F may have a one-body shape (e.g., may be integrally formed).

The cover layer SCV and the digitizer DTM are disposed under the support plate PLT. The cover layer SCV is disposed to overlap the folding area FAO. The digitizer DTM may include a first digitizer DTM-1 and a second digitizer DTM-2 that overlap the first support portion PLT-1 and the second support portion PLT-2, respectively. A portion of each of the first digitizer DTM-1 and the second digitizer DTM-2 may be disposed under the cover layer SCV.

The sixth adhesive layer AL6 couples the support plate PLT and the digitizer DTM to each other, and the seventh adhesive layer AL7 couples the cover layer SCV and the support plate PLT to each other. The sixth adhesive layer AL6 may include a first portion AL6-1 that couples the first support portion PLT-1 and the first digitizer DTM-1 to each other and a second portion AL6-2 that couples the second support portion PLT-2 and the second digitizer DTM-2 to each other.

The cover layer SCV may be disposed between the first portion AL6-1 and the second portion AL6-2 in the second direction DR2. The cover layer SCV may be spaced apart from the digitizer DTM to prevent interference with the digitizer DTM in an unfolded state of the display device DD. The sum of the thickness of the cover layer SCV and the thickness of the seventh adhesive layer AL7 may be less than the thickness of the sixth adhesive layer AL6.

The cover layer SCV may cover (e.g., may extend over) the openings OP in the folding portion PLT-F. In a folded state of the display device DD, the cover layer SCV is elongated to prevent foreign matter from infiltrating into the expanded openings OP. The cover layer SCV may have a lower elastic modulus than the support plate PLT. For example, the cover layer SCV may include thermoplastic polyurethane, rubber, or silicone, but is not limited thereto.

The digitizer DTM, also called an EMR sensing panel, includes a plurality of loop coils that generate a magnetic field at a reference (or preset) resonant frequency with an electronic pen. The magnetic field formed by the loop coils is applied to an LC resonance circuit of the electronic pen that includes an inductor (a coil) and a capacitor. The coil generates a current by the received magnetic field and transfers the generated current to the capacitor. Accordingly, the capacitor charges the current input from the coil and discharges the charged current to the coil. In turn, a magnetic field at a resonant frequency is emitted from the coil. The magnetic field emitted by the electronic pen may be reabsorbed by the loop coils of the digitizer. Accordingly, a location on a touch screen that the electronic pen is close to may be determined.

The first digitizer DTM-1 and the second digitizer DTM-2 may be different digitizers configured to be driven independently of each other or may be different parts of a single digitizer. The digitizer DTM may further include a flexible circuit board that electrically connects the first digitizer DTM-1 and the second digitizer DTM-2.

FIG. 6A is a side view illustrating an unfolded state of the electronic device ED according to an embodiment of the present disclosure. FIG. 6B is a side view illustrating a folded state of the electronic device ED according to an embodiment of the present disclosure.

FIGS. 6A and 6B illustrate only some of the components of the electronic device ED illustrated in FIG. 4A, and the hinge assembly HA is additionally illustrated in FIGS. 6A and 6B. The hinge assembly HA is coupled to the display device DD and the housing HM. The display device DD is also coupled to the housing HM. The coupling thereof may be performed through, for example, an adhesive layer AL. A portion of the hinge assembly HA may be coupled to the housing HM, and the lowermost member of the display device DD may be coupled to the hinge assembly HA. The protective member PP of the display device DD may be coupled to the housing HM.

As illustrated in FIG. 6A, when the electronic device ED is in the unfolded state, the folding area FAO may define substantially one plane together with the first non-folding area NFA10 and the second non-folding area NFA20. The expression “define substantially one plane” used herein is not limited to a plane in a mathematical sense. The folding area FAO in the unfolded state has a much smaller curvature than the folding area FAO in the folded state to be described below. In addition, the deformation of the folding area FAO caused by a very large number of folding and unfolding operations is ignored on the “substantially one plane”.

In FIG. 6A, for detailed description of the hinge assembly HA, the folding area FAO is illustrated to be larger than the first non-folding area NFA10 and the second non-folding area NFA20. However, in practice, the folding area FAO has a substantially smaller area than the first non-folding area NFA10 and the second non-folding area NFA20.

When compared to that in FIG. 6A, the folding area FAO of the display device DD may be deformed to have a curvature area CV and an inverse curvature area ICV in the folded state of the electronic device ED illustrated in FIG. 6B. The inverse curvature area ICV is defined between the curvature area CV and the first non-folding area NFA10 and between the curvature area CV and the second non-folding area NFA20. A non-curvature area may be additionally located between the curvature area CV and the inverse curvature area ICV. The curvature area CV has a diameter greater than the distance between the first non-folding area NFA10 and the second non-folding area NFA20 in the folded state.

The deformation of the display device DD may be caused by the operation of the hinge assembly HA. The hinge assembly HA includes a center frame CF, a first frame FR1, and a second frame FR2. The first frame FR1 and the second frame FR2 may be paired and may be disposed on the opposite sides of the center frame CF. The center frame CF is disposed to correspond to the folding area FAO, and the first frame FR1 and the second frame FR2 are paired and disposed in each of the first non-folding area NFA10 and the second non-folding area NFA20.

The hinge assembly HA will be described with focus on the pair of first and second frames FR1 and FR2. The first frame FR1 may be hinged to the center frame CF through a first shaft RX1 located inside the center frame CF. The second frame FR2 may be hinged to the center frame CF through a second shaft RX2 located inside the center frame CF. The second shaft RX2 may be located farther away from the display device DD than the first shaft RX1. The first frame FR1 may be coupled to the housing HM, and the second frame FR2 may be coupled to the display device DD.

In the unfolded state shown in FIG. 6A, the distances from the first shaft RX1 and the second shaft RX2 to the side surface of the housing HM (e.g., the end of the housing HM) may be substantially the same as each other. However, in the folded state shown in FIG. 6B, the distances from the first shaft RX1 and the second shaft RX2 to the side surface of the housing HM may be different from each other. In the folded state shown in FIG. 6B, the second shaft RX2 may be disposed farther away from the side surface of the housing HM than the first shaft RX1.

The second frame FR2 may be a sliding plate. The second frame FR2 may be moved along a sliding slit SH, and the position of the second frame FR2 may be fixed by a sliding holder SHD. The configuration of the second frame FR2 is not limited thereto, and it is sufficient that the adhesive member AL2, to be described below, is stretched due to the sliding of the second frame FR2.

The second frame FR2 may be moved such that the distance to the side surface of the housing HM is variable in the unfolded state shown in FIG. 6A and the folded state shown in FIG. 6B. In the unfolded state shown in FIG. 6A, the second frame FR2 may be moved relatively close to the side surface of the housing HM and relatively far away from the center frame CF. In contrast, in the folded state shown in FIG. 6B, the second frame FR2 may be moved relatively far away from the side surface of the housing HM and relatively close to the center frame CF.

Accordingly, a gap DT may occur between the side surface of the housing HM and the second frame FR2. The gap DT may be hundreds of micrometers or less. The gap DT may be in a range from about 400 μm to about 700 μm.

When the electronic device ED is changed from the unfolded state shown in FIG. 6A to the folded state shown in FIG. 6B, a slip phenomenon may occur in the display module DM. In contrast, when the electronic device ED is changed from the folded state to the unfolded state, the slip phenomenon is eliminated. The slip phenomenon occurring in the present disclosure is defined as “reverse slip”, and a detailed description thereof will be given below.

The display module DM is not fractured and the slip phenomenon occurs in the display module DM when the electronic device ED is repeatedly deformed (hereinafter, the deformation of the electronic device ED) between the unfolded state shown in FIG. 6A and the folded state shown in FIG. 6B because the plurality of adhesive layers AL1 to AL7 (see, e.g., FIG. 5A) are located between the components of the display module DM. When the electronic device ED is deformed, shear stresses are applied to the stacked components of the display module DM and the adhesive layers therebetween. Depending on the stacked positions, the magnitudes of the shear stresses applied to the stacked components and the adhesive layers therebetween may be different from one another. An adhesive layer to which a large magnitude of shear stress is applied is subjected to larger deformation (e.g., elongation). Because the amounts of deformation (e.g., elongation) of the adhesive layers are different from one another depending on the stacked positions, the slip phenomenon occurs in the display module DM.

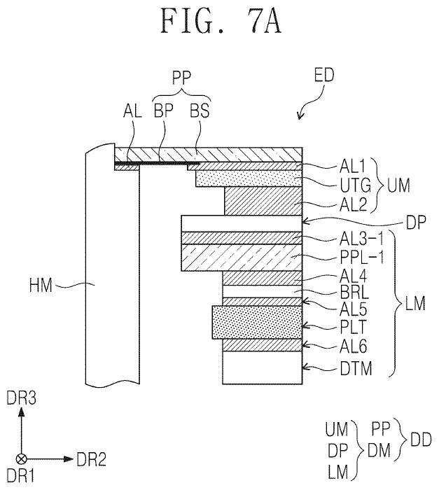

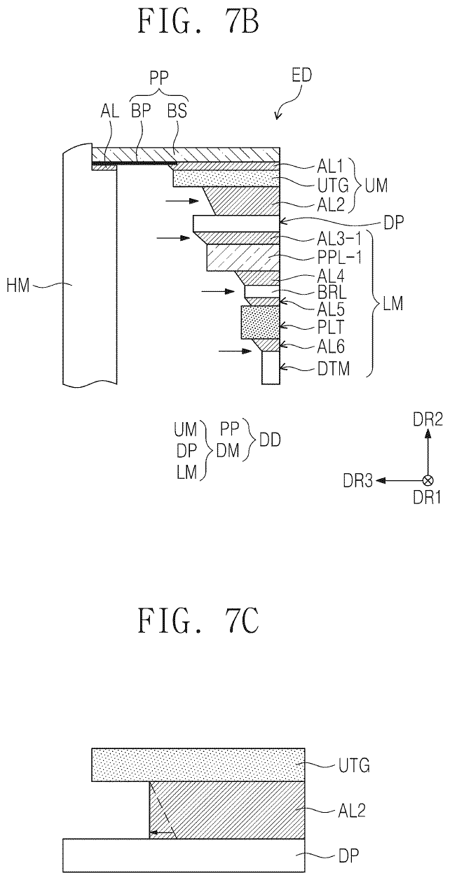

FIGS. 7A and 7B are cross-sectional views illustrating some components of the electronic device ED according to an embodiment of the present disclosure. FIG. 7C is an enlarged cross-sectional view illustrating some components of the electronic device ED according to an embodiment of the present disclosure.

FIG. 7A illustrates some components in the electronic device ED in the unfolded state illustrated in FIG. 6A, and FIG. 7B illustrates some components in the electronic device ED in the folded state illustrated in FIG. 6B. When compared to FIG. 7A, FIG. 7B illustrates that a slip phenomenon occurs in the display module DM. FIG. 7C is an enlarged view for explaining a slip phenomenon of the adhesive member AL2 from among the components of the display module DM illustrated in FIGS. 7A and 7B. Hereinafter, description of the same components described above with reference to FIGS. 1 to 6A will be omitted or only briefly repeated, and the above-described contents may be applied to the same reference numerals.

Referring to FIG. 7A, the display device DD may be coupled to the housing HM. The display device DD may include the protective member PP, and the protective member PP may be coupled to the housing HM through the adhesive layer AL. Accordingly, a path along which external foreign matter infiltrates into the electronic device ED may be blocked. Although the bezel pattern BP is illustrated as being disposed in the area overlapping the housing HM, the present disclosure is not limited thereto. The bezel pattern BP may be removed or moved to another location, and the base layer BS may be coupled to the housing HM through the adhesive layer AL.

The display device DD may include the adhesive member AL2, and the adhesive member AL2 may be disposed between the glass substrate UTG and the display panel DP and may attach the glass substrate UTG and the display panel DP to each other. The adhesive member AL2 may have a thickness of about 30 μm to about 150 μm. For example, the adhesive member AL2 may have a thickness in a range of about 50 μm to about 100 μm.

The adhesive member AL2 has a stress relaxation (SR) in a range of about 70% to about 85%. In this specification, a stress relaxation for a specific layer is given by Equation 1 below. The stress relaxation is measured using a DHR3 rheometer, manufactured by TA instrument, Inc., at a temperature of 25° C. and a shear strain of 25%.

$$SR = [ 1 - ( {X}_{2} / {X}_{1} ) ] \times 100 \% \qquad Equation 1$$

X₁ is a first shear stress measured immediately after application of 25% shear strain to the specific layer at a temperature of 25° C., and X₂ is a second shear stress measured 1 hour after the application of 25% shear strain to the specific layer at a temperature of 25° C.

Because the stress relaxation of the adhesive member AL2 has a numerical range of about 70% to about 85%, the display device DD and the electronic device ED that include the adhesive member AL2 may satisfy both folding characteristics and durability. When the electronic device ED is repeatedly deformed between the unfolded state shown in FIG. 6A and the folded state shown in FIG. 6B described above, the adhesive member AL2 has to simultaneously satisfy both recovery, which is the ability to return to its original shape after deformation, and stress relaxation over time, which has a trade-off relationship with the recovery. Unlike than in embodiments of the present disclosure, when the stress relaxation of the adhesive member AL2 is less than about 70%, the stress relaxation may be lowered, and when the stress relaxation of the adhesive member AL2 exceeds about 85%, the recovery may be lowered, resulting in low reliability.

The creep strain (CS) of the adhesive member AL2 may be in a range from about 100% to about 150%. In this specification, a creep strain for a specific layer is given by Equation 2 below. The creep strain represents the rate of change of shear strain in a long-term period (600 seconds) on the basis of shear strain in an initial period (7.5 seconds) when a stress of 1 N is applied for 600 seconds at a temperature of 25° C. The creep strain is measured using the DHR3 rheometer manufactured by TA instrument, Inc.

$$CS = [ ( {Y}_{2} / {Y}_{1} ) - 1 ] \times 100 \% \qquad Equation 2$$

Y₁ is a shear strain in the 7.5 second period after a stress of 1 N is applied to the specific layer for 600 seconds at a temperature of 25° C., and Y₂ is a shear strain in the 600 second period.

Unlike than in embodiments of the present disclosure, when the creep strain is less than about 100%, impact resistance or folding characteristics may be lowered, and when the creep strain exceeds about 150%, durability may be lowered or a problem of delamination may occur, resulting in low reliability.

The display device DD may include the first adhesive layer AL1, and the first adhesive layer AL1 may be disposed between the protective member PP and the glass substrate UTG and may attach the protective member PP and the glass substrate UTG to each other. Hereinafter, the first adhesive layer AL1 may be referred to as an upper adhesive member. The display device DD may include the third adhesive layer AL3, and the third adhesive layer AL3 may be disposed between the panel protection layer PPL and the display panel DP and may attach the panel protection layer PPL and the display panel DP to each other. Hereinafter, the third adhesive layer AL3 may be referred to as a first lower adhesive member. The display device DD may include the fourth adhesive layer AL4 and the fifth adhesive layer AL5. The fourth adhesive layer AL4 may couple the panel protection layer PPL and the barrier layer BRL to each other, and the fifth adhesive layer AL5 may couple the barrier layer BRL and the support plate PLT to each other. Hereinafter, the fourth adhesive layer AL4 or the fifth adhesive layer AL5 may be referred to as a second lower adhesive member.

The stress relaxation of the upper adhesive member AL1, the first lower adhesive member AL3, or the second lower adhesive member AL4 or AL5, which is given by Equation 1 above, may range from about 70% to about 85%. The creep strain of the upper adhesive member AL1, the first lower adhesive member AL3, or the second lower adhesive member AL4 or AL5 may range from about 100% to about 150%. Accordingly, the display device DD and the electronic device ED that include the adhesive layers AL1 to AL5 may satisfy both folding characteristics and durability.

Unlike than in embodiments of the unfolded state shown in FIG. 7A, in the folded state shown in FIG. 7B, shear stresses are applied to the adhesive layers AL1 to AL8, and the adhesive layers AL1 to AL8 are elongated to cause a slip phenomenon in the display module DM. The slip phenomenon in the display module DM that occurs in the folded state is caused by the operation of the hinge assembly HA described above with reference to FIGS. 6A and 6B. As the amount of slip is accumulated toward the lower member LM from the upper member UM, the slip between the protective member PP and the lower member LM may be greater than the slip between the protective member PP and the display panel DP. The lower member LM moves more than the display panel DP with respect to the protective member PP.

When the electronic device ED is changed from the unfolded state shown in FIG. 7A to the folded state shown in FIG. 7B, the display module DM may slip in a reverse direction, which is a direction away from the housing HM. Because the protective member PP disposed on the upper side of the display module DM has a structure coupled to the housing HM, the display module DM may slip in the reverse direction away from the housing HM without slipping in a direction toward the housing HM.

In contrast, when the electronic device ED is changed from the folded state shown in FIG. 7B to the unfolded state shown in FIG. 7A, the slip phenomenon in the display module DM is eliminated (or reversed). Accordingly, the position of at least a portion of the display module DM may be changed in the direction toward the housing HM. FIG. 7C illustrates a change in the position of the adhesive member AL2 when the electronic device ED is changed from the folded state shown in FIG. 7B to the unfolded state shown in FIG. 7A. The adhesive member AL2 may be stretched in the direction toward the housing HM when the electronic device ED is changed from the folded state shown in FIG. 7B to the unfolded state shown in FIG. 7A.

The display device according to the embodiment of the present disclosure may include the adhesive member that has a stress relaxation of about 70% to about 85% and that is at least partially stretched when changed from the folded state to the unfolded state, thereby satisfying both high stress relaxation and high recovery. When the unfolded state and the folded state are repeated, shear stress may be applied to the adhesive member and may be accumulated in the adhesive member. However, the adhesive member according to the embodiment of the present disclosure may have a stress relaxation in a range of about 70% to about 85%, thereby overcoming the aforementioned problem. In addition, although the stress relaxation and the recovery have a trade-off relationship, the adhesive member according to embodiments of the present disclosure, when changed from the folded state to the unfolded state, may be at least partially stretched through elimination of a slip phenomenon to substantially increase the recovery, thereby improving both the stress relaxation and the recovery. Accordingly, the display device and the electronic device that include the adhesive member according to embodiments of the present disclosure may secure excellent durability and reliability despite repeated folding.

Hereinafter, results obtained by evaluating characteristics of an electronic device according to an embodiment of the present disclosure will be described with reference to FIGS. 1 to 7C described above, an embodiment, and a comparative example. In addition, the embodiment below is an example for a better understanding of the present disclosure, and the spirit and scope of the present disclosure is not limited thereto.

### Evaluation of Stress Relaxation

The embodiment and the comparative example below identically have the structure of the display device DD illustrated in FIG. 5A, except that the adhesive members AL2 have different characteristics. The characteristics of the adhesive members AL2 included in the embodiment and the comparative example are shown in Table 1 below. In Table 1 below, the stress relaxation was measured using the DHR3 rheometer, manufactured by TA instrument, Inc., at a temperature of 25° C. and a shear strain of 25%. The creep strain represents the rate of change of shear strain in a long-term period on the basis of shear strain in an initial period when a stress of 1 N is applied for 600 seconds at a temperature of 25° C. The creep strain was measured using the DHR3 rheometer manufactured by TA instrument, Inc.

TABLE 1

| | Adhesive member (AL2) | |
|---|---|---|
| | Stress | Creep |
| | relaxation | strain |
| Embodiment | 70% | 100% |
| Comparative | 55% | 55% |
| example | | |

Referring to Table 1, the stress relaxation of the adhesive member AL2 of the embodiment is in the range of 70% to 85%, whereas the stress relaxation of the adhesive member AL2 of the comparative example has a value of less than 70%. In addition, the creep strain of the adhesive member AL2 of the embodiment is in the range of 100% to 150%, whereas the creep strain of the adhesive member AL2 of the comparative example has a value of less than 100%. The display device and the electronic device including the same according to the embodiment of the present disclosure may have improved stress relaxation in a foldable device.

### Evaluation of Recovery

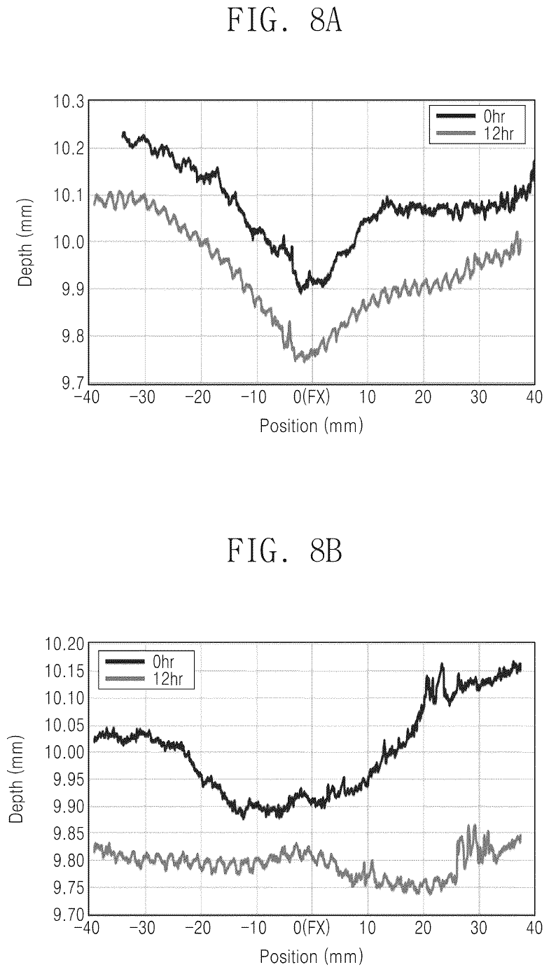

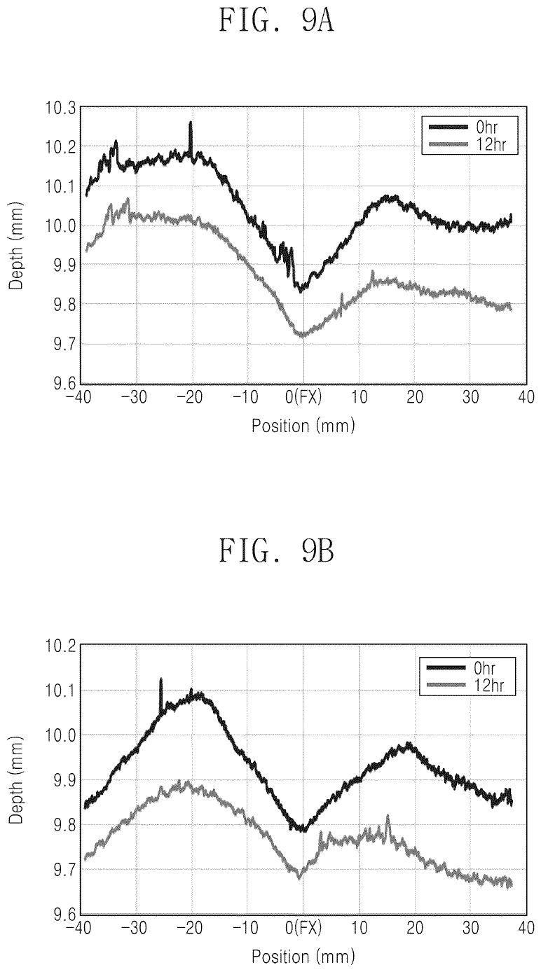

FIGS. 8A and 8B are graphs measured for calculation of a crease reduction rate of an electronic device of an embodiment. FIGS. 9A and 9B are graphs measured for calculation of a crease reduction rate of an electronic device of a comparative example. FIGS. 8A, 8B, 9A, and 9B are graphs depicting crease depths after 0 and 12 hours in an unfolded state after a folding operation is repeatedly performed on the electronic devices under specific conditions for about 1 hour. In each of FIGS. 8A, 8B, 9A, and 9B, the folding axis FX is illustrated as position 0.

FIG. 8A illustrates experimental results for an electronic device in which a display device including the adhesive member AL2 of the embodiment is coupled to a hinge assembly that causes forward slip, and FIG. 8B illustrates experimental results for an electronic device in which a display device including the adhesive member AL2 of the embodiment is coupled to the hinge assembly HA of the embodiment that causes reverse slip. The degree to which the crease depth measured through FIG. 8B is reduced when compared to the crease depth measured through FIG. 8A is calculated as a “crease reduction rate” and is shown in Table 2 below.

FIG. 9A illustrates experimental results for an electronic device in which a display device including the adhesive member of the comparative example described above is coupled to a hinge assembly that causes forward slip, and FIG. 9B illustrates experimental results for an electronic device in which a display device including the adhesive member of the comparative example described above is coupled to the hinge assembly HA of the embodiment that causes reverse slip. The degree to which the crease depth measured through FIG. 9B is reduced when compared to the crease depth measured through FIG. 9A is calculated as a “crease reduction rate” and is shown in Table 2 below.

TABLE 2

| | Crease | Crease |
|---|---|---|
| | reduction | reduction |
| | rate | rate |
| | (0 hr) | (12 hr) |
| Embodiment | 48% | 119% |
| Comparative | 27% | 29% |
| example | | |

Referring to Table 2, the electronic device of the embodiment has a higher crease reduction rate than the electronic device of the comparative example. Accordingly, the electronic device according to the embodiment of the present disclosure may have improved recovery in a foldable device.

The display device and the electronic device including the same according to the embodiments of the present disclosure may include the adhesive member having a stress relaxation of about 70% to about 85% and the hinge assembly that causes reverse slip. Accordingly, the stress relaxation and the recovery having a trade-off relationship may be secured to a certain level or higher, and thus the reliability of the devices may be improved.

According to the embodiments of the present disclosure, the display device and the electronic device including the same may include the adhesive member and the hinge assembly. Accordingly, both the stress relaxation and the recovery may be secured to a certain level or higher, and thus the reliability of the devices may be improved.

While the present disclosure has been described with reference to embodiments thereof, it will be apparent to those of ordinary skill in the art that various changes and modifications may be made thereto without departing from the spirit and scope of the present disclosure as set forth in the following claims and their equivalents.

What is claimed is:

1. A display device comprising:
a display panel having a first non-folding area, a second non-folding area, and a folding area between the first non-folding area and the second non-folding area;
a glass substrate over the display panel; and
an adhesive member between the display panel and the glass substrate,
wherein the adhesive member has a stress relaxation (SR) in a range of 70% to 85%, and
wherein the stress relaxation (SR) of the adhesive member is given by Equation 1:
$$SR = [ 1 - ( {X}_{2} / {X}_{1} ) ] \times 100 \%$$
wherein, X₁ is a first shear stress measured immediately after application of 25% shear strain at a temperature of 25° C., and X₂ is a second shear stress measured 1 hour after the application of 25% shear strain at a temperature of 25° C.

2. The display device of claim 1, wherein the folding area extends in a first direction, and
wherein the first non-folding area and the second non-folding area are spaced apart from each other in a second direction crossing the first direction.

3. The display device of claim 1, wherein the adhesive member comprises a pressure sensitive adhesive.

4. The display device of claim 1, wherein the adhesive member has a creep strain in a range of 100% to 150% at a temperature of 25° C.

5. The display device of claim 1, wherein the adhesive member is directly on the display panel.

6. The display device of claim 1, wherein the adhesive member has a thickness in a range of 30 μm to 150 μm.

7. The display device of claim 1, further comprising:
a protective member over the glass substrate; and
an upper adhesive member between the protective member and the glass substrate,
wherein the upper adhesive member has a stress relaxation in a range of 70% to 85%, and the stress relaxation of the upper adhesive member is given by the Equation 1.

8. The display device of claim 1, further comprising:
a panel protection layer under the display panel; and
a first lower adhesive member between the display panel and the panel protection layer,
wherein the first lower adhesive member has a stress relaxation in a range of 70% to 85%, and the stress relaxation of the first lower adhesive member is given by the Equation 1.

9. The display device of claim 8, further comprising:
a support plate under the panel protection layer; and
a second lower adhesive member between the panel protection layer and the support plate,
wherein the second lower adhesive member has a stress relaxation in a range of 70% to 85%, and the stress relaxation of the second lower adhesive member is given by the Equation 1.

10. An electronic device comprising:
a display device comprising:
a display panel;
a glass substrate over the display panel; and
an adhesive member between the display panel and the glass substrate;
a hinge assembly coupled to the display device and configured to convert the display device between an unfolded state and a folded state; and
a housing coupled to the display device and the hinge assembly, wherein the adhesive member has a stress relaxation (SR) in a range of 70% to 85%, and
wherein the stress relaxation (SR) of the adhesive member is given by Equation 1:
$$SR = [ 1 - ( {X}_{2} / {X}_{1} ) ] \times 100 \%$$
wherein, X₁ is a first shear stress measured immediately after application of 25% shear strain at a temperature of 25° C., and X₂ is a second shear stress measured 1 hour after the application of 25% shear strain at a temperature of 25° C.

11. The electronic device of claim 10, wherein the display device further comprises a protective member on the glass substrate, and
wherein the protective member is attached to the housing.

12. The electronic device of claim 11, wherein the display panel has a first non-folding area, a second non-folding area, and a folding area between the first non-folding area and the second non-folding area.

13. The electronic device of claim 12, wherein the hinge assembly comprises:
a center frame corresponding to the folding area;
a first frame corresponding to the first non-folding area, the first frame being hinged to the center frame through a first shaft located inside the center frame; and
a second frame corresponding to the first non-folding area, the second frame being hinged to the center frame through a second shaft, the second shaft being located inside the center frame and farther away from the display device than the first shaft is, and
wherein the display device is coupled to the second frame.

14. The electronic device of claim 13, wherein the hinge assembly causes a slip between the protective member, the glass substrate, the adhesive member, and the display panel in the folded state.

15. The electronic device of claim 14, wherein the adhesive member slips more than the glass substrate with respect to the protective member, and
wherein the display panel slips more than the adhesive member with respect to the protective member.

16. The electronic device of claim 10, wherein the adhesive member in the unfolded state is at least partially stretched in a direction toward the housing when compared to the adhesive member in the folded state.

17. The electronic device of claim 10, wherein the adhesive member has a creep strain in a range of 100% to 150% at a temperature of 25° C.

18. The electronic device of claim 10, further comprising:
a protective member over the glass substrate; and
an upper adhesive member between the protective member and the glass substrate,
wherein the upper adhesive member has a stress relaxation in a range of 70% to 85%, and the stress relaxation of the upper adhesive member is given by the Equation 1.

19. The electronic device of claim 10, further comprising:
a panel protection layer under the display panel; and
a first lower adhesive member between the display panel and the panel protection layer,
wherein the first lower adhesive member has a stress relaxation in a range of 70% to 85%, and the stress relaxation of the first lower adhesive member is given by the Equation 1.

20. The electronic device of claim 19, further comprising:
a support plate under the panel protection layer; and
a second lower adhesive member between the panel protection layer and the support plate,
wherein the second lower adhesive member has a stress relaxation in a range of 70% to 85%, and the stress relaxation of the second lower adhesive member is given by the Equation 1.
